(19) United States
(12) Patent Application Publication
(10) Pub. No.: US 2025/0119107 A1
(43) Pub. Date: Apr. 10, 2025

(54) BI-DIRECTIONAL AMPLIFIER DEVICE

(71) Applicant: Technetix B.V., Veenendaal (NL)

(72) Inventor: Tom SLEGTER, Veenendaal (NL)

(21) Appl. No.: 18/907,629

(22) Filed: Oct. 7, 2024

(30) Foreign Application Priority Data
Oct. 9, 2023 (GB) 2315459.4

(51) Int. Cl. H03F 3/04; H01P 5/18

(52) U.S. Cl. CPC H03F 3/04; H01P 5/18

(57) ABSTRACT

There is provided a bi-directional amplifier device (10) configured for use in a broadband network comprising a first directional coupler (12) and a second directional coupler (14) connected together so as to create separate upstream and downstream paths (16, 18), an upstream amplifier element (24) located in the upstream signal path (16) and a downstream amplifier element (24′) located in the downstream signal path (18), wherein an isolator unit (40) comprising a digital processor element (56) is connected to an input (45) of the upstream amplifier element (24) and the isolator unit (40) is adapted to digitally filter the upstream signal to remove all downstream signal frequencies before amplification of the upstream signal takes place in the upstream amplifier element (24). The isolator unit (40) further comprises signal converters (58, 60) to convert analogue downstream and upstream signals into digital signals for processing by the digital processor element (56).

### FIELD OF THE INVENTION

This invention relates to a bi-directional amplifier device for use in cable television and broadband networks.

### BACKGROUND OF THE INVENTION

In a broadband network, amplifiers are used to amplify electrical signals from a central network headend down to an individual user (downstream) or from the individual user back to the headend (upstream). In the past the upstream and downstream frequencies were separated in frequency range, the upstream signals using a lower frequency range and the downstream signals using a higher frequency range. In modern networks this can still be the case, but the frequency ranges are more likely to be altered often to give homes an ever faster, more wideband, upstream signal. Whilst at present there is usually a clear split between the downstream and upstream frequencies, the downstream and upstream frequencies might be interleaved, for example with part of the downstream frequency range positioned within the upstream frequency range.

Bi-directional amplifiers that use directional couplers instead of diplex filters have limited isolation which can cause downstream signals to leak into the upstream signal path and vice versa, particularly where the downstream signal spectrum and upstream signal spectrum adjoin. Reflections from the outgoing signals add to the incoming signals which further reduces the signal quality.

### SUMMARY OF THE INVENTION

In accordance with the present invention, there is provided a bi-directional amplifier device, configured for use in a broadband network, comprising a first directional coupler and a second directional coupler connected together so as to create separate upstream and downstream signal paths, an upstream amplifier element located in the upstream signal path and a downstream amplifier element located in the downstream signal path, wherein an isolator unit comprising a digital processor element is connected to an input of the upstream amplifier element and the isolator unit is adapted to digitally filter an upstream signal to remove all downstream signal frequencies before amplification of the upstream signal takes place in the upstream amplifier element. This ensures the upstream amplifier element is no longer loaded with un wanted signal frequencies.

Preferably a third directional coupler is positioned in the downstream signal path, with a coupler port of the third directional coupler connected to the isolator unit thereby to send a sample of the downstream signal to the isolator unit. Typically frequencies up to at least the highest upstream frequency are sampled by the third directional coupler.

The transmitted port or output port of the third directional coupler is preferably connected to an input of the downstream amplifier element, such that the downstream signal passes through the third directional coupler before reaching the downstream amplifier element.

The isolator unit may further comprise signal converters to convert analogue downstream and upstream signals into digital signals for processing by the digital processor element.

Preferably the isolator unit further comprises a digital to analogue signal converter to convert digital signals from the digital processor element to analogue signals for transmission to the upstream amplifier element.

The digital signal processor preferably removes downstream signal frequencies from the upstream signal to create a filtered upstream signal.

The digital processor element may use the filtered upstream signal to improve detection of the downstream spectrum.

The invention will now be described by way of example with reference to the following drawings in which:

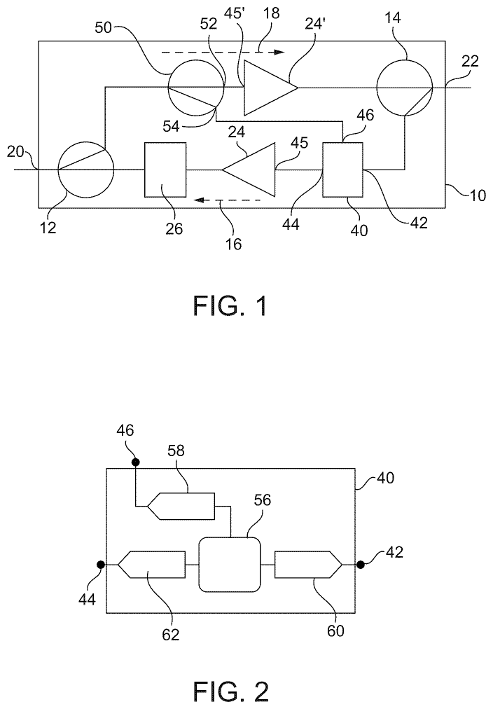

FIG. 1 is a schematic diagram of an embodiment of an amplifier device;

FIG. 2 is a schematic diagram of an isolator unit forming part of the amplifier device;

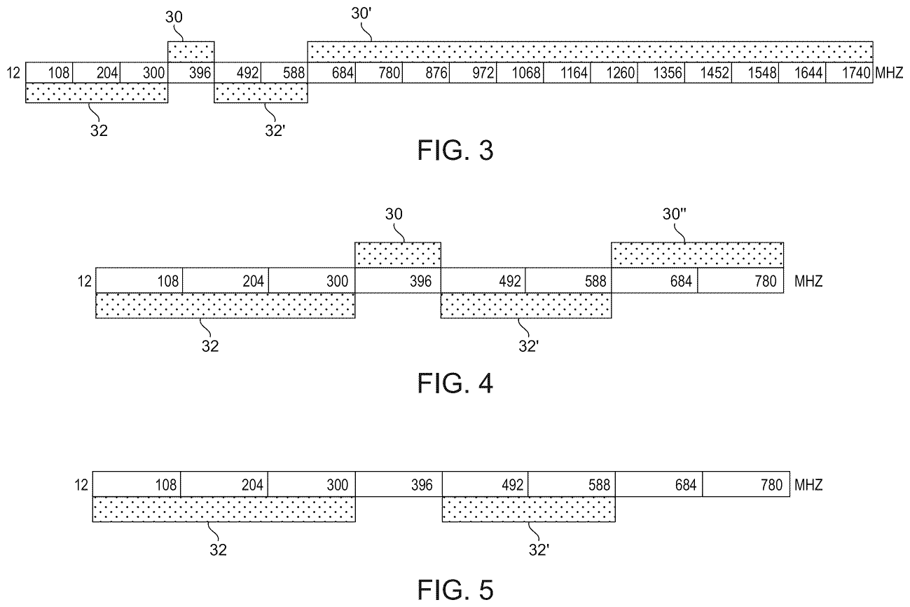

FIG. 3 shows an example of upstream and downstream frequency ranges;

FIG. 4 shows an example of selected downstream frequency ranges sent to the isolator unit;

FIG. 5 shows an example of a cleaned upstream signal;

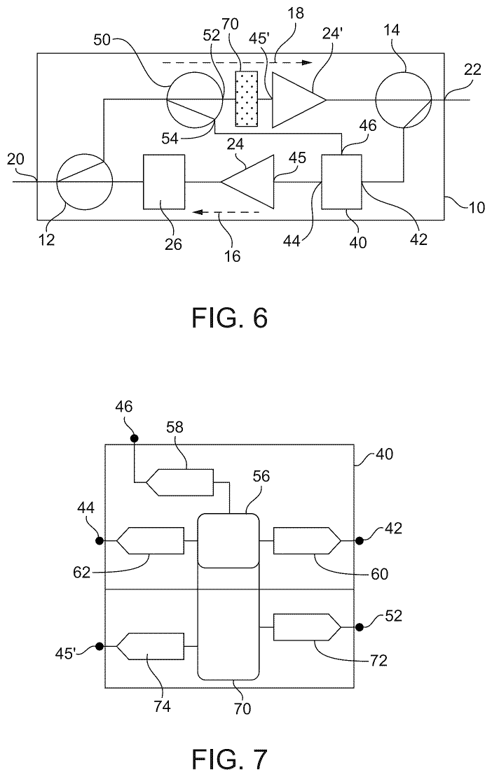

FIG. 6 is a schematic diagram of a second embodiment of an amplifier device; and

FIG. 7 is a schematic diagram of an isolator unit forming part of the second embodiment.

### DESCRIPTION

FIG. 1 shows an amplifier device 10 configured for use in cable television and broadband networks and which comprises two directional couplers 12, 14 connected together to create separate upstream and downstream signal paths 16, 18 between ports 20, 22 with an amplifier element 24, 24′ disposed in each signal path. Amplifier device 10 is bi-directional allowing upstream and downstream signals to pass between a user and a headend associated with a network provider. Optional low pass filter 26 is placed in upstream signal path 16 on the output side of upstream amplifier element 24.

Where downstream and upstream frequency ranges adjoin within the broadband spectrum, the limited isolation of directional couplers 12, 14 can result in downstream signals leaking into the upstream signal path and vice versa. Typically the combined downstream and upstream frequency range spans from 12 MHz to 1800 MHZ, although more extensive frequency ranges are possible. A mid-span frequency range, such as 108 to 684 MHz by way of example, can be used for either upstream or downstream signals, see for example FIG. 3 where the downstream signal frequencies are split into two separated portions 30, 30′, portion 30 within the mid-span range and extending between 300 to 396 MHz and portion 30′ extending over 588 to 1740 MHz. Upstream signal frequencies are split into two portions 32, 32′, portion 32 extending over 12 to 300 MHz and portion 32′ extending over 396 to 588 MHz. Thus portion 30 of the downstream frequencies is interleaved between the two portions 32, 32′ of the upstream signal. Isolation of downstream and upstream signals is needed to avoid overloading amplifier elements 24, 24′ and to reduce any reflected signals.

Amplifier device 10 further comprises an isolation unit 40 positioned in upstream signal path 16 and having an input 42 connected to directional coupler 14 and an output 44 connected to the input of upstream amplifier element 24. A downstream signal input 46 also forms part of isolation unit 40, downstream input 46 connected to downstream path 18 by way of a further directional coupler 50 positioned in downstream path 18 between directional coupler 12 and downstream amplifier element 24′. Transmitted or output port 52 of directional coupler 50 connects to an input 45′ of element 24′ and coupled port 54 directs part of the downstream signal to downstream input 46.

Frequencies up to at least the highest upstream frequency are sampled by directional coupler 50, although typically the downstream spectrum will be sampled by directional coupler 50 for around 200 MHz above the highest upstream frequencies. For the example as shown in FIG. 4, the downstream signal portion 30 and a selected part 30″ of the higher frequency part 30′ of the downstream signal running from 588 to 780 MHz is sampled.

Isolation unit 40 further comprises a digital signal processor 56, analogue-to-digital converters (ADC) 58, 60 and a digital to analogue converter (DAC) 62, see FIG. 2. Downstream analogue signals received through input 46 from directional coupler 50 are converted by ADC 58 into digital signals which are sent to processor 56. Similarly upstream input 42 receives analogue signals which are converted by ADC 60 into digital signals which are received by processor 56.

Processor 56 detects and analyses the frequency ranges within the downstream signal and for the example of FIG. 3, calculates that frequency ranges 301 to 396 MHz and 589 to 780 MHz are used as downstream segments. Processor 56 then filters the detected downstream frequencies from the digital upstream frequencies to improve isolation and passes this cleaned upstream signal to DAC 62 for conversion to an analogue signal which is fed through output 44 to be amplified by upstream amplifier element 24. The upstream signal then just comprises the frequencies shown in FIG. 5 with no contaminating frequencies from the downstream signal.

By sampling the downstream spectrum, using processor 56 to determine actual downstream spectrum use, and digitally filtering the upstream signal, the processed upstream spectrum is cleaned to remove unwanted frequencies. This provides improved amplification performance as upstream amplifier element 24 is no longer loaded with unwanted frequencies. This adaptive isolation technique will also substantially remove reflections and echoes that enter the amplifier device in the upstream direction.

Where dynamic change takes place of upstream and downstream frequencies, processor 56 can continually sample the downstream signal and the processor actively remove downstream frequencies from the upstream signal.

For this purpose the isolator unit can be enhanced to also filter in the downstream direction. Isolator unit 40 is connected between output port 52 of directional coupler 50 and to input 45′ of the downstream amplifier element 24′ as shown in FIG. 6 where element 70 represents this connection as shown in more detail in FIG. 7. Isolator unit 40 further comprises a downstream ADC 72 and a downstream DAC 74 such that downstream analogue signals from output port 52 are routed via downstream ADC 72 through processor 56 for filtering before conversion back to analogue signals at downstream DAC 74, then returning to enter input 45′ of amplifier element 24′. Isolator unit 40 is thus extended to digitally filter the downstream signal to remove any reflected upstream signal frequencies before amplification takes place in downstream amplifier element 24′. This ensures the downstream amplifier element is no longer loaded with unwanted frequencies. The processor 56 can perform the additional isolator function as it already knowns which downstream frequencies are not in use and can therefore be filtered.

Processor 56 can be split into two modules for upstream and downstream filtering to aid practical implementation.

1. A bi-directional amplifier device comprising a first directional coupler and a second directional coupler connected together so as to create separate upstream and downstream signal paths, an upstream amplifier element located in the upstream signal path and a downstream amplifier element located in the downstream signal path, wherein an isolator unit comprising a digital processor element is connected to an input of the upstream amplifier element and the isolator unit is adapted to digitally filter an upstream signal to remove all downstream signal frequencies before amplification of the upstream signal takes place in the upstream amplifier element.

2. A bi-directional amplifier device according to claim 1, wherein a third directional coupler is positioned in the downstream signal path, with a coupler port of the third directional coupler connected to the isolator unit.

3. A bi-directional amplifier device according to claim 2, wherein the transmitted port or output port of the third directional coupler is connected to an input of the downstream amplifier element.

4. A bi-directional amplifier device according to claim 1, wherein the isolator unit further comprises signal converters to convert analogue downstream and upstream signals into digital signals for processing by the digital processor element.

5. A bi-directional amplifier device according to claim 1, wherein the isolator unit further comprises a digital to analogue signal converter to convert digital signals from the digital processor element to analogue signals for onwards transmission to the upstream amplifier element.

6. A bi-directional amplifier device according to claim 5, wherein the isolator unit further comprises a digital to analogue signal converter to convert digital signals from the digital processor element to analogue signals for onwards transmission to the downstream amplifier element.

7. A bi-directional amplifier device according to claim 1, wherein the digital signal processor removes downstream signal frequencies from the upstream signal to create a filtered upstream signal.

8. A bi-directional amplifier device according to claim 1, wherein the digital signal processor removes upstream signal frequencies from the downstream signal to create a filtered downstream signal.

9. A bi-directional amplifier device according to claim 1, wherein the digital processor element uses the filtered upstream signal to improve detection of the downstream spectrum.
